(19) United States
(12) Patent Application Publication
(10) Pub. No.: US 2010/0301378 A1
(43) Pub. Date: Dec. 2, 2010

(54) ILLUMINATION DEVICE AND METHOD FOR THE PRODUCTION THEREOF

(75) Inventors: Bakuri Lanchava, Regensburg (DE); Robert Kraus, Regensburg (DE)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/677,828

(22) PCT Filed: Sep. 12, 2008
(86) PCT No.: PCT/EP2008/007587

§ 371 Date: Mar. 12, 2010

(30) Foreign Application Priority Data
Sep. 12, 2007 (DE) 10 2007 043 401.6

(51) Int. Cl. H01L 33/52; H01L 21/56

(52) U.S. Cl. 257/100; 438/26; 257/E33.059; 257/E21.502

(57) ABSTRACT

A method for producing an illumination device is provided. The method may include providing a carrier, on which illumination means are applied, with filler material; applying an upper exterior layer on the filler material; reducing the arrangement formed by the carrier, filler material and upper exterior layer to a predetermined thickness; wherein the carrier is a flex-board, which is equipped with the illumination means.

The invention relates to an illumination device and to a method for producing the illumination device.

Existing LED illumination devices often have the disadvantages that they are not very robust and the methods for producing them are comparatively elaborate.

It is an object of the invention to avoid the disadvantages mentioned above and, in particular, to propose an illumination device which has great robustness and to provide an efficient method for producing it.

This object is achieved according to the features of the independent patent claims. Refinements of the invention may be found in the dependent claims.

In order to achieve the object, a method for producing an illumination device is first provided,
in which a carrier, on which illumination means are applied, is provided with filler material;
in which an upper exterior layer is applied on the filler material;
in which the arrangement consisting of the carrier, filler material and upper exterior layer is reduced to a predetermined thickness.

A robust illumination device is produced in this way, the reduction to the desired thickness being carried out in particular at a predetermined temperature. The filler material ensures great strength or robustness of the illumination device and, in particular after the filler material has hardened, separation into illumination sub-devices is possible for example by means of sawing.

In one refinement, the illumination means is a light-emitting diode.

In another refinement, the thickness is adjusted with the aid of at least one roller, in particular with the aid of two rollers.

In a further refinement, the carrier is a flex-board, which is equipped with the illumination means.

In a further configuration, the filler material is introduced between the carrier and the upper exterior layer.

In the scope of production, the filler material may thus be introduced between layers and then the illumination device may be reduced to a predetermined thickness.

According to another configuration, the filler material comprises one of the following materials:
plastic, in particular thermoplastic or foam;
paper.

For reinforcement, the filler material may include or consist of glass fibers, carbon fibers or rock powder.

In particular, the filler material may have at least one of the following properties:
water-repellent;
transparent;
semitransparent.

In one refinement, the upper exterior layer has openings.

In a further refinement, a protective layer is applied between the filler material and the upper exterior layer.

In a further configuration, a lower exterior layer is applied below the carrier layer.

According to a subsequent refinement, an adhesive layer is applied between the carrier layer and the lower exterior layer.

In another configuration, a plug unit is provided on the carrier layer. In particular, the plug unit may include a plug and a socket, the plug and the socket engaging in one another.

In the scope of one refinement, separation is carried out along a connecting axis between the plug and the socket.

This separation may in particular be carried out by sawing along the connecting axis, the separation being carried out so that the plug unit is not damaged or destroyed.

According to a subsequent configuration, the separation is carried out along the connecting axis, in particular by means of sawing from above and below and/or from at least one side.

In an alternative refinement, the plug socket comprises two sockets and/or a double socket. In particular, the two sockets may be configured integrally.

In a further configuration, pins are fitted into the two sockets. In particular, separation may be carried out along the connecting axis of the two sockets. Such separation may be carried out by sawing along the connecting axis.

It is also possible for a double socket, into which pins have been inserted, to be separated, in particular sawed, along a target separation point.

The aforementioned object is likewise achieved by an illumination device produced by the method described herein.

The aforementioned method is furthermore achieved by an illumination device including
a carrier layer including illumination means;
an upper exterior layer;
a filler material, which is provided between the upper exterior layer and the carrier layer.

In one refinement, the carrier layer is a flex-board equipped with the illumination means.

In particular, the illumination means may be a light-emitting diode (LED).

The filler material may include one of the following materials:
plastic, in particular thermoplastic or foam;
paper.

For reinforcement, the filler material may include or consist of glass fibers, carbon fibers or rock powder.

The filler material may furthermore have at least one of the following properties:
water-repellent;
transparent;
semitransparent.

According to another refinement, the upper exterior layer has openings.

In a further refinement, a protective layer is provided between the filler material and the upper exterior layer.

According to a further configuration, a lower exterior layer is provided below the carrier layer, the lower exterior layer consisting in particular of an aluminum alloy.

An adhesive layer may furthermore be provided between the carrier layer and the lower exterior layer.

It is also possible for a plug unit to be provided on the carrier layer.

In the scope of another configuration, the illumination device has a cutting plane along a side face.

Exemplary embodiments of the invention will be presented and explained below with the aid of the drawings, in which:

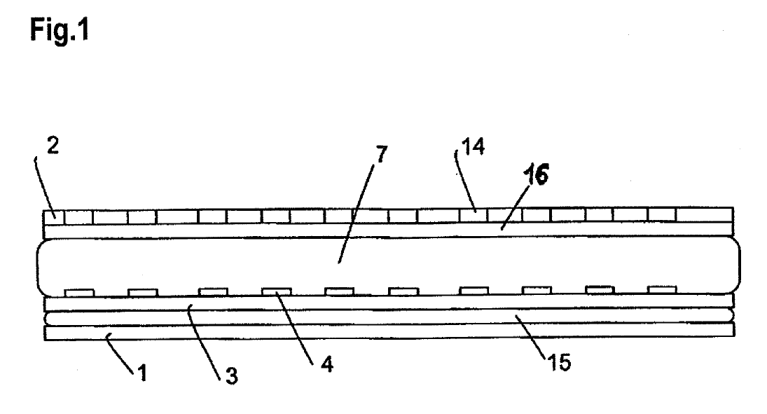

FIG. 1 shows a schematic cross section through an illumination device;

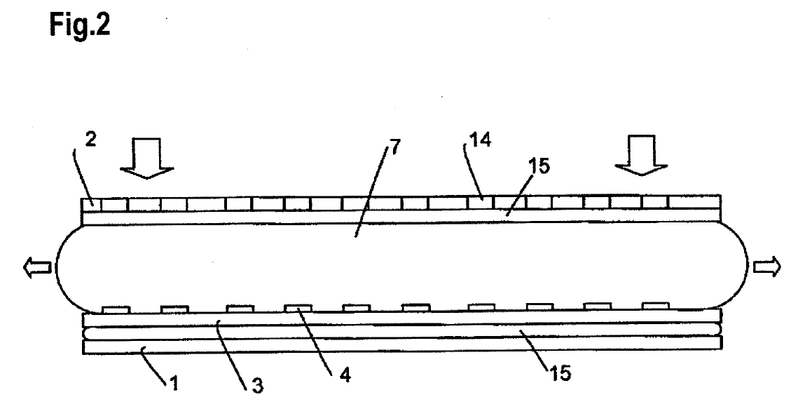

FIG. 2 shows a process of compressing the illumination device to a predetermined thickness;

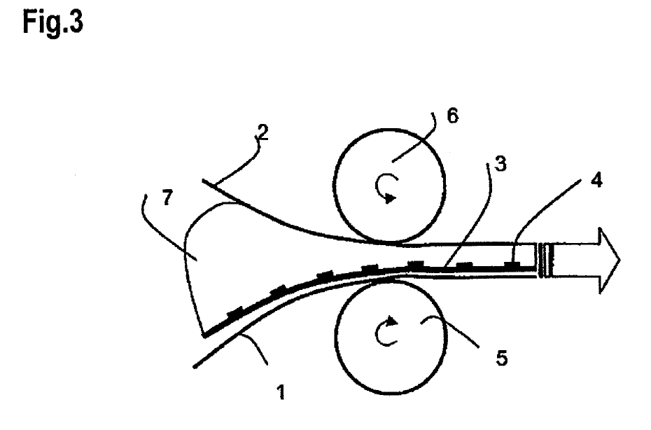

FIG. 3 shows a schematic representation in which the reduction of the height of the arrangement to the predetermined thickness is achieved with the aid of two rollers;

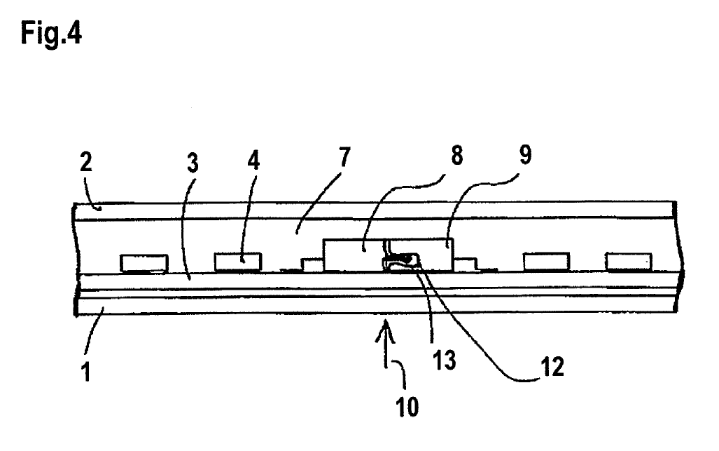

FIG. 4 shows an illumination device comprising a plug and a socket, the illumination device having a target separation point on a connection between the two;

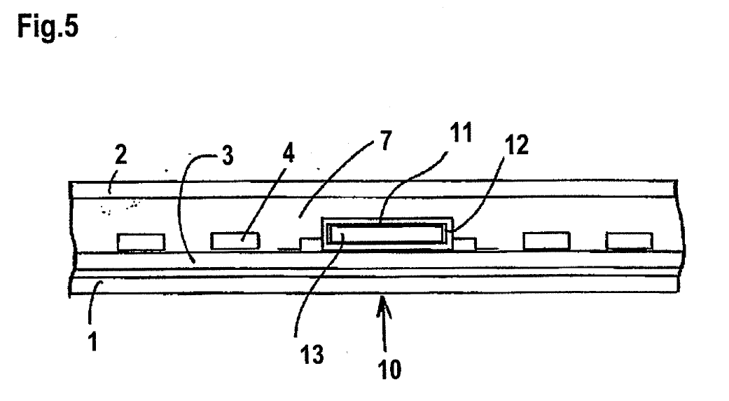

FIG. 5 shows an illumination device comprising a double socket, the illumination device having a target separation point through the double socket.

FIG. 1 shows a schematic cross section through the illumination device, including a flex-board 3 which is equipped with illumination means, here LEDs 4. The flex-board 3 is connected by an adhesive layer 15 to a lower exterior layer 1. The filler material 7 is provided on the flex-board 3, a protective layer 16 is applied on the filler material 7, and above this an upper exterior layer 2 which in particular has openings 14 is applied.

The illumination device proposed here has in particular a lower exterior layer 1, an equipped LED module (flex-board 3 with LEDs 4) and filler material 7, and an upper exterior layer 2. The rest of the components shown in FIG. 1 are optional, and some or all of them may supplement the illumination device.

The exterior layers 1 and 2 essentially have a protective function in relation to the illumination device. They are in particular configured so that light can emerge through the exterior layers 1 and/or 2 respectively surface-wide or for example only at points intended for this.

In particular, the exterior layers 1 and 2 may have at least one of the following properties:
at least partially transparent;
diffusely scattering;
openings at predetermined points.

It is furthermore possible to configure the exterior layers 1 and/or 2 at least partially as a reflective layer depending on the application in question (for example diffusely or specularly, metallically reflective, or the like).

An LED module includes in particular the carrier with the LEDs, in particular a flex-board equipped with LEDs or a circuit board equipped with LEDs.

The LED module may be configured as a functional illumination module with illumination means, in particular with light-emitting diodes, which have different colors. The illumination module may furthermore have electrical leads, circuits, for example current limiters or drivers, as well as connection contacts, which are arranged on a support. This support may be used as the lower exterior layer 1 of the illumination device.

In particular, the connections or connection contacts may be configured so that the illumination device can be separated easily into subregions. In this case a modular concept of a plurality of illumination devices (which can be plugged together) may preferably be implemented, so that a large linear or two-dimensional illumination device can be produced efficiently.

In particular, one of the following materials may be provided as filler material:
plastic;
thermoplastic;
foam.

In this case, the filler material preferably has at least one of the following properties:
water-repellent;
transparent;
semitransparent.

The approach proposed here is preferably also suitable for producing a two-dimensional illumination device, and in particular a linear illumination device.

The equipped flex-board 3 is provided with filler material 7. The upper exterior layer 2 is applied onto the filler material 7 and compressed to a predetermined thickness. Excess filler material 7 can escape sideways during this (see FIG. 2).

In particular, different functional units, that is to say different carriers with different components and different functions, may in this case be assembled in the form of strips (“endless strips”) in a rolling method.

FIG. 3 shows a schematic representation in which the reduction of the height of the arrangement to the predetermined thickness is achieved with the aid of two rollers 5 and 6. At a predetermined temperature, the individual layers are combined (rolled) to form a layer system. The exterior layers 1, 2 are preferably made of an aluminum alloy, and are correspondingly pressed together from above and below by the rollers 6 and 5. In particular, the filler material is thereby shaped into a filler layer.

Optionally, an adhesive layer 15 may be provided between the first exterior layer 1 and the flex-board 3 and/or between the filler material 7 and the second exterior layer 2. An adhesive layer may also be provided between the equipped flex-board 3 and the filler material 7.

Another aspect of the solution approach proposed here is that a plug unit is provided on the carrier layer. Such a plug unit is used for example as a plug concept for connection of further components, for example lamps. In particular, the plug concept may be used in order to plug together a plurality of illumination (sub-)devices, in particular two-dimensional ones, after they have been separated, so as to provide two-dimensional lamps in virtually any desired shape and with virtually any desired size.

According to FIG. 4, to this end so-called male-female pairs (i.e. plugs 8 and sockets 9) are arranged, in particular soldered, on or along a so-called target separation point 10. The effect achieved by dividing (for example sawing) the illumination device at this target separation point 10 is that the plugs 8 and sockets 9 can be extracted from one another. In particular, during separation it is necessary to ensure that the plug-socket pair is not damaged. This may for example be achieved by sawing the illumination device from above and below, and optionally from at least one side.

Preferably, the flex-board 3 is configured and provided with target separation points 10 so that, after separation, the illumination (sub-)device obtained has an equal number of plugs 8 and sockets 9 on opposite ends (or sides), so that the illumination (sub-)devices thereby obtained are suitable to be joined together in blocks.

In an alternative embodiment according to FIG. 5, the flex-board 3 is equipped along the target separation point 10 with two sockets or a (one-piece) double socket 11, the sockets preferably being connected together by inserted pins 13. When separating, for example sawing, along the target separation point 10, the pins 13 are cut or sawed through. This creates essentially smooth surfaces, i.e. openings in the sockets 11 filled by the pin stubs. The pin stubs are finally pushed deep into the socket by the prongs of the plug during the actual plugging process. Unused sockets therefore remain protected from external effects by the spin stubs.

### Further Advantages:

The approach proposed here allows mass production of illumination devices with virtually arbitrarily large (illumination) surfaces for use, for example, as building walls, interior wall coverings, etc.

Mechanical properties, and in particular robustness of the illumination device can furthermore be increased significantly with the aid of the sandwich structure proposed here.

The exterior layers and the filler layer are also suitable as protection from external effects, for example moisture. This achieves greater reliability of the illumination device.

The proposed plug concepts allow reliable connection, with secure contact, of the illumination device even after it is separated (for example by means of the sawing into subregions).

### LIST OF REFERENCES

1 lower exterior layer
2 upper exterior layer
3 carrier, in particular flex-board
4 light-emitting diode, LED
5 lower roller
6 upper roller
7 filler material
8 plug
9 socket
10 target separation point
11 double socket
12 socket hole
13 plug pin
14 openings in the exterior layer
15 adhesive layer
16 protective layer

1. A method for producing an illumination device, the method comprising:
providing a carrier, on which illumination means are applied, with filler material;
applying an upper exterior layer on the filler material;
reducing the arrangement formed of the carrier, filler material and upper exterior layer to a predetermined thickness;
wherein the carrier is a flex-board, which is equipped with the illumination means.

2. (canceled)

3. The method as claimed in claim 1, wherein the thickness is adjusted with the aid of at least one roller.

4. (canceled)

5. The method as claimed in claim 1, wherein the filler material is introduced between the carrier and the upper exterior layer.

6. The method as claimed in claim 1, wherein the filler material comprises at least one of the following materials:
plastic;
thermoplastic;
foam;
paper;
glass fibers;
carbon fibers; and
rock powder.

7. The method as claimed in claim 1, wherein the filler material has at least one of the following properties:
water-repellent;
transparent;
semitransparent.

8. (canceled)

9. The method as claimed in claim 1, wherein the upper exterior layer has openings.

10. (canceled)

11. (canceled)

12. (canceled)

13. The method as claimed in claim 1, wherein a plug unit is provided on the carrier layer.

14. The method as claimed in claim 13, wherein the plug unit comprises a plug and a socket, the plug and the socket engaging in one another.

15. The method as claimed in claim 14, wherein separation is carried out along a connecting axis between the plug and the socket.

16. The method as claimed in claim 15, wherein the separation is carried out along the connecting axis.

17. The method as claimed in claim 13, wherein the plug socket comprises at least one of two sockets and a double socket.

18. The method as claimed in claim 17, wherein the two sockets are configured integrally.

19. The method as claimed in claim 17, wherein pins are fitted into the two sockets.

20. (canceled)

21. An illumination device produced by a method, the method comprising:
providing a carrier, on which illumination means are applied, with filler material;
applying an upper exterior layer on the filler material;
reducing the arrangement formed by the carrier, filler material and upper exterior layer to a predetermined thickness;
wherein the carrier is a flex-board, which is equipped with the illumination means.

22. An illumination device, comprising:
a carrier layer comprising illumination means;
an upper exterior layer;
a filler material, which is provided between the upper exterior layer and the carrier layer;
wherein the carrier layer is a flex-board equipped with the illumination means.

23. (canceled)

24. The illumination device as claimed in claim 22, wherein the illumination means is a light-emitting diode.

25. The illumination device as claimed in claim 22, wherein the filler material comprises at least one of the following materials:
plastic;
thermoplastic;
foam;
paper
glass fibers;
carbon fibers; and
rock powder.

26. The illumination device as claimed in claim 22, wherein the filler material has at least one of the following properties:
water-repellent;
transparent;
semitransparent.

27. (canceled)

28. (canceled)

29. (canceled)

30. (canceled)

31. (canceled)

32. The illumination device as claimed in claim 22, wherein a plug unit is provided on the carrier layer.

33. The illumination device as claimed in claim 22, having a cutting plane along a side face.
